(19) United States
(12) Patent Application Publication
(10) Pub. No.: US 2025/0254812 A1
(43) Pub. Date: Aug. 7, 2025

(54) EXPLOSION-PROOF HOUSING WITH REINFORCEMENT ASSEMBLY

(71) Applicant: R. Stahl Schaltgeräte GmbH, Waldenburg (DE)

(72) Inventor: Kai-Uwe WOLPERT, Krautheim (DE)

(21) Appl. No.: 18/835,118

(22) PCT Filed: Feb. 2, 2023
(86) PCT No.: PCT/EP2023/052554

§ 371 Date: Aug. 1, 2024

(30) Foreign Application Priority Data
Feb. 7, 2022 (DE) 10 2022 102 793.7

(51) Int. Cl. H05K 5/13

(52) U.S. Cl. CPC H05K 5/13

(57) ABSTRACT

The present disclosure relates to an explosion-proof housing with a non-metal first housing part and a non-metal second housing part which are bonded together at a connection point in order to close off an inner volume of the explosion-proof housing in an explosion-proof or ignition-proof manner from an explosive atmosphere. Each housing part has at least one reinforcement assembly which is arranged in the region of the connection point between the two housing parts. Each reinforcement assembly has a reinforcement protrusion and a metal reinforcement element. Upon establishment of the connection between the housing parts, preferably one respective reinforcement assembly of the first housing part and one respective reinforcement assembly of the second housing part lie opposite each other. The reinforcement assemblies lying opposite each other can additionally optionally be connected to each other by means of at least one coupling element, preferably a metal coupling element.

### CROSS REFERENCE TO RELATED APPLICATIONS

This application is a National Stage of PCT Application No. PCT/EP2023/052554 filed on Feb. 2, 2023, which claims priority to German Patent Application No. DE 10 2022 102 793.7 filed on Feb. 7, 2022, the contents each of which are incorporated herein by reference thereto.

### TECHNICAL FIELD

The present disclosure refers to an explosion-proof housing for use in explosive environments. The explosion-proof housing has an interior, which is surrounded in explosion-proof manner relative to the environment. In the interior potential ignition sources can be arranged that could result in an ignition of an explosive atmosphere in the environment. Such ignition sources can be, for example, electrical and/or electronic devices or operating means. The explosion-proof housing is configured to avoid an ignition of the explosive atmosphere in the environment of the housing outside of the interior, even in case flames, hot gases, sparks, arcs or the like are created in the interior.

### BACKGROUND

DE 10 2012 111 393 A1 describes an explosion-proof housing. It comprises two housing parts made of plastic that are connected with one another by two friction welding seams.

The friction welding seams are subject to high stress, if an explosion should occur in the interior of the housing. The housing has to withstand an explosion pressure in order to avoid that ignitable media, such as hot gases, sparks, flames or the like, get into the explosive atmosphere in the environment. Such housings are only allowed to be used in explosive environments, if they fulfill standardized test conditions and therefore guarantee a sufficient safety. The test conditions are defined in the standard IEC 60079-1. For example, housings having a specific interior volume have to withstand an interior pressure in the range of approximately 1000 kPa up to 2000 kPa for at least 10 seconds.

Particularly for plastic housings it has shown that due to variations in the manufacturing process, a remarkably more stable constructive configuration of the plastic housing is necessary in order to reliably comply with the test requirements. This in turn results in a high material consumption and thus high costs, for example due to larger wall thicknesses of the plastic housing. For cost reasons and to save resources, this is however undesired.

### BRIEF SUMMARY

It can be considered as object of the present disclosure to provide a non-metallic explosion-proof housing that can be manufactured with low material consumption and that guarantees compliance with the standardized test requirements.

This object is solved by an explosion-proof housing having a non-metallic first housing part surrounding a first interior accessible via a first housing opening, wherein the first housing opening is completely surrounded in circumferential direction by a first flange that includes a first connection surface completely surrounding the first housing opening, a non-metallic second housing part surrounding a second interior accessible via a second housing opening, wherein the second housing opening is completely surrounded in circumferential direction by a second flange that includes a second connection surface completely surrounding the second housing opening, wherein the first housing part and the second housing part are connected to one another at the first connection surface and second connection surface facing one another in a substance bond manner and/or by means of adhesion, wherein the first housing part adjacent to the first connection surface outside the first interior and the second housing part adjacent to the second connection surface outside the second interior respectively comprise at least one reinforcement projection having a metallic reinforcement element attached thereon respectively.

The explosion-proof housing according to the present disclosure includes a non-metallic first housing part and a non-metallic second housing part. The two housing parts consist preferably of plastic or a composite material comprising a plastic matrix in which reinforcing elements or reinforcing fibers are embedded. For example, the composite material can contain reinforcing fibers of glass and/or carbon. As plastic for the housing parts or for the matrix of the housing parts consisting of composite material, particularly a thermoplastic is used.

The first housing part surrounds the first interior accessible via a first housing opening. The housing opening is completely surrounded by a first flange in a circumferential direction. On the first flange a first connection surface is present, which completely surrounds the first housing opening in circumferential direction.

The second housing part is configured analog to the first housing part. It surrounds a second interior, which is accessible via a second housing opening. The second housing opening is completely surrounded by a second flange in the circumferential direction. On the second flange a second connection surface is present, which completely surrounds the second housing opening in circumferential direction.

By means of the two connection surfaces, the two housing parts can be connected with one another in a substance bond manner and/or by means of adhesion. With the connection established the two connection surfaces are arranged opposite one another. They can be directly connected with each other in a substance bond manner, for example by producing a welding connection, such as a laser welding connection, an ultrasonic welding connection or a friction welding connection. Additionally or alternatively, an adhesive layer can be present between the connection surfaces or at least between a respective section of the first connection surface and the second connection surface.

The substance bond connection and/or the connection created by adhesion between the first housing part and the second housing part is preferably fluid tight.

For reinforcement and/or stiffening each housing part includes adjacent to the respective connection surface and outside of the respective interior at least one reinforcement projection. The reinforcement projection extends in circumferential direction preferably only partly around the respective housing opening. In case of a polygonal housing opening, the reinforcement projection extends at least along one section of one side and preferably not continuously over multiple sides.

The reinforcement projection is integrally or monolithically configured with the respective housing part in a preferred embodiment.

The reinforcement projection can have a bar-like configuration. Particularly, it extends obliquely or orthogonal outwardly away from the respective housing part. With the connection between the first housing part and the second housing part established, each reinforcement projection of the first housing part can abut against a reinforcement projection of the second housing part or can be arranged with distance opposite thereto.

Preferably each reinforcement projection is not configured in a solid manner, but includes multiple hollow spaces that, for example, can be formed by a grid-like structure. The hollow spaces can be open at least at one side of the reinforcement projection, for example on the side facing away from the respective other housing part.

Each reinforcement projection has respectively one metallic reinforcement element attached thereon and preferably releasably attached thereon, being part of a common reinforcement assembly. In circumferential direction the length of the metallic reinforcement element corresponds substantially to the length of the reinforcement projection, wherein the length of the reinforcement element attached to a reinforcement projection can be at least 80% or at least 90% or at least 95% of the length of the reinforcement projection.

Due to the at least one additional reinforcement assembly consisting respectively of one reinforcement projection and one metallic reinforcement element attached thereto respectively, the housing parts are additionally reinforced or stiffened at the side. In case of substantially cuboid-shaped housing parts or other polygonal housing parts, it is advantageous to attach one reinforcement assembly at each side that exceeds a minimum length. The minimum length can be, for example, 10 cm or 15 cm or 20 cm.

By means of a housing part reinforced in this manner, the explosion-proof housing can also reliably withstand the required test pressure or explosion pressure, also with comparably small wall thicknesses. Bulging of the housing due to a high interior pressure are reduced or avoided in the area of the reinforcement assembly. In doing so, shearing stresses and peeling stresses on the substance bond connection and/or the adhesive connection can be reduced remarkably.

In a preferred embodiment the first housing opening and the second housing opening are substantially rectangular. The housing openings can also have other polygonal and/or round shapes. In other embodiments the housing openings can be circular. The two housing openings have particularly identical size and shape.

The first connection surface can directly adjoin the first housing opening or can be separated therefrom by means of an edge or web section. Particularly, the first connection surface does not project beyond the wall of the housing into the first housing opening. Analog to this the second connection surface can directly adjoin the second housing opening or can be separated therefrom by means of an edge or web section. Particularly, the second connection surface does not project into the second housing opening.

In a preferred embodiment the first housing opening and the second housing opening are at least in sections orientated parallel to a plane that is spanned by a longitudinal direction and a transverse direction. A height direction extends orthogonal to the longitudinal direction and orthogonal to the transverse direction. The longitudinal direction, the transverse direction and the height direction form a Cartesian coordinate system.

It is advantageous, if the first housing part includes one reinforcement projection or one reinforcement assembly respectively on two opposite sides. Analog to this, the second housing part can comprise on two opposite sides one reinforcement projection or one reinforcement assembly respectively. The reinforcement projections of the first housing part and the reinforcement projections of the second housing part can be arranged opposite in pairs respectively. The shape and size of the reinforcement projections of a common pair can be identical, particularly in transverse direction and in longitudinal direction.

It is preferred, if a reinforcement projection of the second housing part is arranged opposite to each reinforcement projection of the first housing part or vice versa. Thereby exactly one reinforcement projection of the second housing part can be arranged opposite to each reinforcement projection of the first housing part. The oppositely arranged reinforcement projections are preferably connected with one another by means of a coupling device. For example, the coupling device can be releasably attached to the explosion-proof housing. The coupling device is located outside of the first interior and outside of the second interior.

A releasable connection, for example a screw connection, can be established between the opposite reinforcement projections or the reinforcement projections assigned to one another by means of the coupling device. Alternatively to a releasable connection, the connection established by means of the coupling device can also be a non-releasable connection, for example a rivet connection.

Each coupling device includes at least one coupling element and preferably at least two coupling elements, such as at least one screw, at least one bolt, at least one bracket or another suitable mechanical coupling element. The at least one coupling element is preferably a metallic element. The at least one coupling element connects the two opposing reinforcement projections and particularly establishes a connection between the reinforcement elements on the opposing reinforcement projections. For this purpose, the at least one coupling element can be in contact with the two reinforcement elements and can particularly urge them and particularly pull them toward one another.

Due to the at least one coupling device of the explosion-proof housing, the two housing parts can be additionally mechanically pressed against one another so-to-speak, which reduces the stress on the substance bond connection or adhesive connection in case of an explosion in the interior of the housing.

It is advantageous, if each metallic reinforcement element is plate-shaped or strip-shaped. In an embodiment each metallic reinforcement element can be a metallic reinforcement sheet material.

Preferably a length of the metallic reinforcement element parallel to the circumferential direction is longer than a width orthogonal to the circumferential direction. The length of the reinforcement element can be, for example, at least about the factor 5 or at least about the factor 10 longer than the width of the reinforcement element.

Preferably each metallic reinforcement element is releasably arranged on the respectively assigned reinforcement projection and can, for example, loosely abut against the respective reinforcement projection. In a preferred embodiment the metallic reinforcement element is supported on a grid structure or a grid profile of the assigned reinforcement projection. An entirely two-dimensional abutment between the reinforcement element and the reinforcement projection is possible, but not necessary.

In an embodiment the first connection surface and/or the second connection surface includes at least one connection projection, which is closed in a ring-shaped manner in circumferential direction. Such a connection projection is particularly advantageous, if the material of the connection projection is used for producing a welded joint between the two housing parts. Each connection projection can form a welded joint, particularly friction welded joint between the first housing part and the second housing part.

It is advantageous, if each reinforcement projection and each reinforcement element is arranged at least in a center section along the respective side of the housing part. This configuration particularly applies to housing parts having a substantially polygonal housing opening. It is not required that the reinforcement projection extends over the whole adjacent side of the housing part. It can be arranged with distance to the corner areas respectively at which the side of the housing part transitions into another side of the housing part.

Each housing part can comprise one or more stiffening assemblies. It is advantageous, if each reinforcement projection and each reinforcement element arranged thereon is arranged partly or entirely in circumferential direction along a stiffening assembly of the housing part. In this manner the effect of the reinforcement assembly (reinforcement projection with reinforcement element arranged thereon) and the stiffening assembly can complement one another.

Preferably, the length of the stiffening assembly and/or the adjacent reinforcement projection and/or the reinforcement element in circumferential direction is minimum 50% of the length of the respective side of the housing part in circumferential direction. Due to this dimensioning, bulging of the respective side of the housing part in case of an explosion in the interior can be avoided or reduced particularly effectively.

In an embodiment each stiffening assembly includes multiple stiffening ribs. The stiffening ribs can be particularly orientated orthogonal or obliquely to the plane in which the respective housing opening extends. Particularly the stiffening ribs extending at the outer side of the respective housing part away from the flange.

Preferably each flange has a web that is arranged with distance to the adjacent wall section of the respective housing part. Between the web and the wall section an interstice is formed. The stiffening ribs can at least partly extend into the interstice. The stiffening ribs can be connected to the web and the wall section.

### BRIEF DESCRIPTION OF THE DRAWINGS

Advantageous embodiments of the explosion-proof housing are derived from the dependent claims, the description and the drawings. In the following, preferred embodiments of the explosion-proof housing are explained in detail based on the attached drawings. The drawings show:

FIG. 1 a perspective illustration of an embodiment of an explosion-proof housing,

FIG. 2 a longitudinal section through the embodiment of the explosion-proof housing of FIG. 1,

FIG. 3 a perspective illustration of a first housing part of the explosion-proof housing according to FIGS. 1 and 2,

FIG. 4 a perspective illustration of a second housing part of the explosion-proof housing according to FIGS. 1 and 2,

FIGS. 5 and 6 a highly schematical basic illustration of the effect of the reinforcement assemblies in an explosion-proof housing according to the present disclosure respectively.

### DETAILED DESCRIPTION

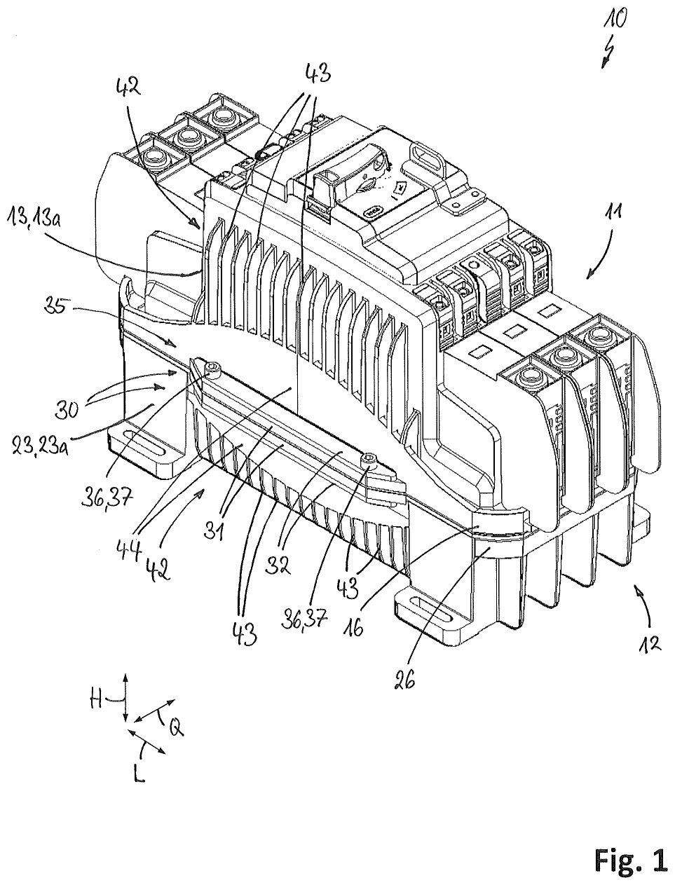

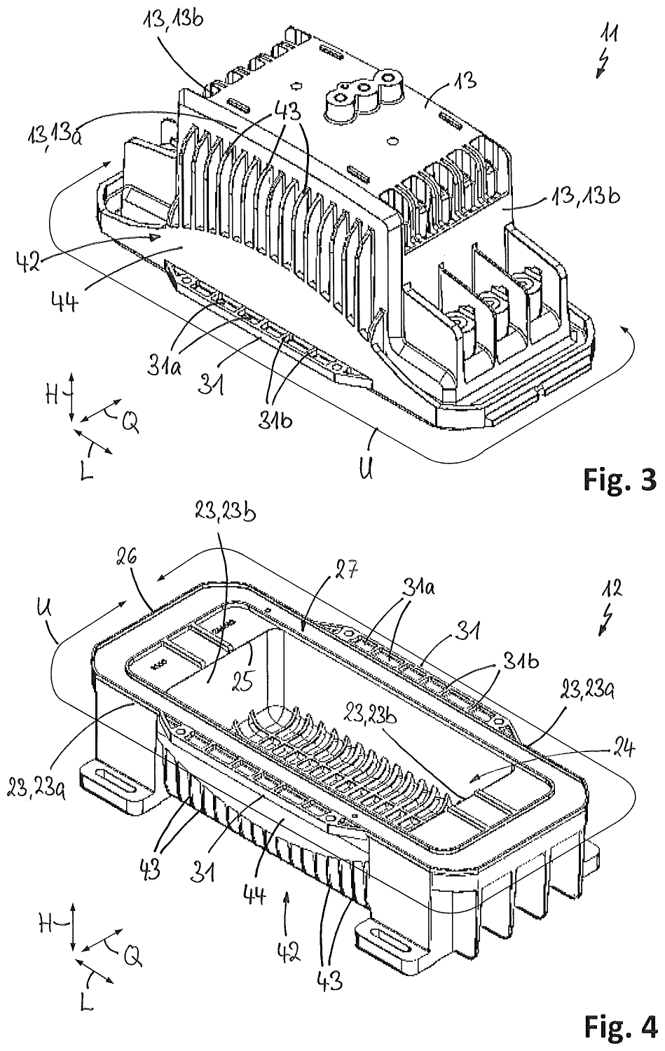

An embodiment of an explosion-proof housing 10 according to the present disclosure is illustrated in FIG. 1. The explosion-proof housing 10 has a first housing part 11 (FIG. 3) as well as a second housing part 12 (FIG. 4). The first housing part 11 can be denoted as cover and the second housing part 12 can be denoted as cup. The two housing parts 11, 12 are connected with one another in a substance bond manner and/or by means of an adhesive connection layer. In the embodiment a substance bond connection by producing a welded connection, particularly a friction welded connection is established, preferably exclusively. The connection between the two housing parts 11, 12 can be denoted as non-releasable connection.

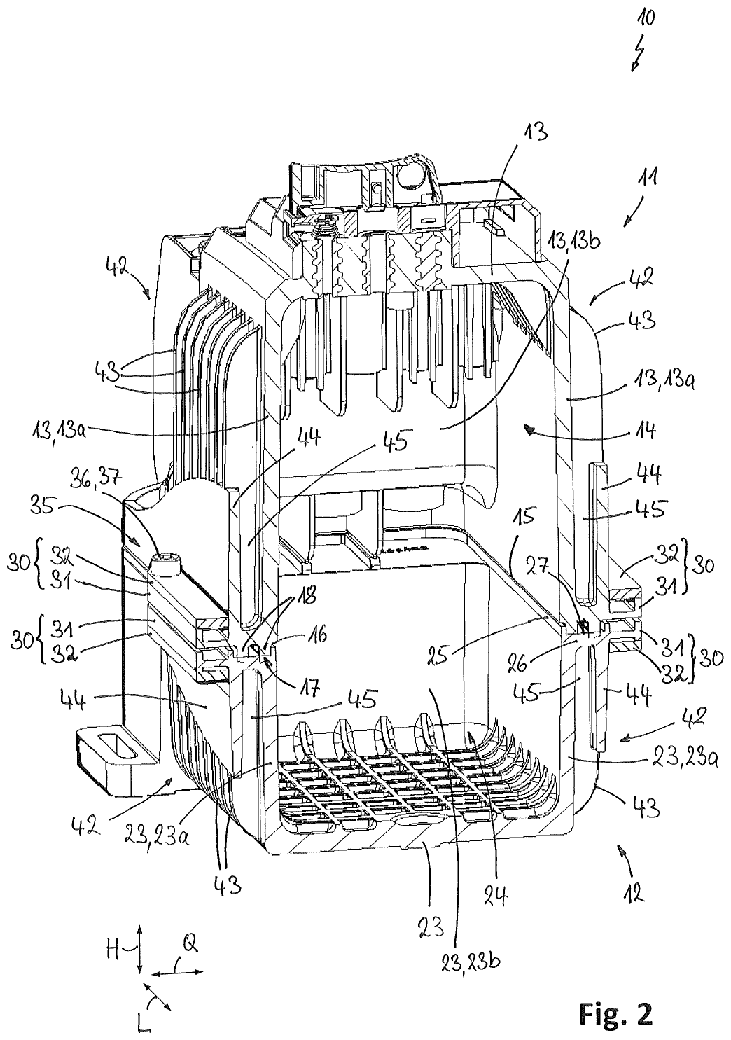

The first housing part 11 comprises multiple first wall sections 13 that surround a first interior 14 (compare particularly FIG. 2). The first interior is accessible at one side by means of a first housing opening 15.

The housing opening 15 is completely surrounded in a ring-shaped manner by means of a first flange 16 of the first housing part 11 in a circumferential direction U around the first housing opening 15. The circumferential direction U is schematically illustrated in FIG. 3. On first flange 16 a first connection surface 17 is present that completely surrounds first housing opening 15 in circumferential direction U in a ring-shaped manner. In the embodiment illustrated here the first connection surface 17 extends in sections or entirely parallel to a plane in which the housing opening 15 is located. According to the example, this plane is spanned by a longitudinal direction L and a transverse direction Q. A height direction H is orientated orthogonal to the longitudinal direction L and to the transverse direction Q. The longitudinal direction L, the transverse direction Q and the height direction H form a Cartesian coordinate system for the explosion-proof housing 10.

Alternatively to the illustrated preferred embodiment, the first connection surface 17 could be inclined at least in sections relative to the height direction H, so that the first housing part 11 expands starting from the first housing opening 15 along the first connection surface 17 outwardly.

As apparent from FIG. 2, first connection surface 17 extends not entirely along one single plane in the embodiment, but comprises at least one and according to the example, two connection projections 18. The first connection surface 17 has, therefore, a stepped shape. The connection projections 18 extend in circumferential direction U entirely around the first housing opening 15. According to the example, they serve for abutment and for substance bond connection with the second housing part 12.

The second housing part 12 is substantially configured analog to the first housing part 11. The second housing part 12 comprises multiple second wall sections 23 surrounding a second interior 24. The second interior 24 is accessible on one side via a second housing opening 25.

The second housing opening 25 is surrounded completely in circumferential direction by a second flange in a ring-shaped manner on which a second connection surface 27 is present. The second connection surface 27 completely surrounds the second housing opening 25 in circumferential direction U.

In the embodiment illustrated here the second connection surface 27 extends in sections or entirely parallel to a plane which is spanned by longitudinal direction L and transverse direction Q. In modification to this the second connection surface 27 can be at least in sections orientated also obliquely relative to the height direction H. The orientation of the two connection surfaces 17, 27 is adapted to one another, so that they extend at each position in circumferential direction U substantially parallel to one another when the connection is established.

The two housing parts 11, 12 are non-metallic housing parts 11, 12 and consist in the embodiment of plastic or a composite material having a plastic matrix. The plastic can be a thermoplastic in both cases.

By means of the connection surfaces 17, 27 the substance bond connection and/or the adhesive connection is established between the two housing parts 11, 12. For example, the material provided by the at least one connection projection 18 can be used for producing a welded joint (melting and re-curing of the material). The two housing parts 11, 12 can thereby be pressed against one another, so that during solidification of the melted material a substance bond connection is created between the two housing parts 11, 12. Each connection projection 18 can thus form a weld seam, which is completely closed in circumferential direction U. For example, the welding can be carried out by friction welding, laser beam welding, ultrasonic welding or the like.

When the connection between the two housing parts 11, 12 is established, first interior 14 and second interior 24 form a housing interior of the explosion-proof housing 10, which can have a substantially cuboid-shaped contour. The outer and/or inner form of the explosion-proof housing 10 or the housing parts 11, 12 can vary.

The two housing openings 15, 25 are substantially rectangular with preferably rounded corner areas according to the example. Also, other polygonal shapes of the housing openings 15, 25 can be realized. It is also possible to realize circular or elliptical housing openings 15, 25, for example in case of substantially cylindrical or circular cylindrical explosion-proof housings 10.

Each housing part 11, 12 comprises on at least one side a reinforcement assembly 30. The reinforcement assembly 30 has a reinforcement projection 31 as well as a reinforcement element 32 of metal or a metal alloy arranged thereon respectively. According to the example, the metallic reinforcement element 32 is mechanically and preferably releasably attached to the reinforcement projection 31, for example by means of a screw connection or comparable mechanical attachment elements. According to the example, the reinforcement assemblies are arranged at least in a respective central area of the respective side.

The reinforcement element 32 can be plate-shaped or strip-shaped. It can therefore also be denoted as reinforcement sheet material or reinforcement sheet material strip. The extension of the reinforcement element 32 in longitudinal direction L is longer than the extension in transverse direction Q and according to the example, at least about the factor 5 or at least about the factor 10 longer. The thickness of the reinforcement element 32 in height direction H is preferably at least smaller about the factor 3 to 5 than the extension in transverse direction Q.

The explosion-proof housing 10 has a longer dimension in longitudinal direction L than in transverse direction Q. The wall sections 13, 23 of the two housing parts 11 or 12 arranged on opposite sides of the respective interior 14, 24 in transverse direction Q can thus be also denoted as longitudinal sidewall sections 13a, 23a. The wall sections 13, 23 that are arranged on opposite sides of the respective interior 14 or 24 can be denoted as transverse sidewall sections 13b, 23b. In the embodiment on each longitudinal sidewall section 13a, 23a of each housing part 11, 12 a reinforcement assembly 30 is provided comprising respectively one reinforcement projection 31 and one reinforcement element 32.

The reinforcement assembly can extend in longitudinal direction L along a length, which is shorter than the dimension of the first interior 14 and the second interior 24 in longitudinal direction L in the area of the connection surfaces 17, 27. The length of each reinforcement projection 31 in longitudinal direction L is longer than its width in transverse direction Q and according to the example, at least about the factor 5 or the factor 10 longer.

When the connection between the two housing parts 11, 12 is established, one and according to the example, exactly one reinforcement assembly 30 of second housing part 12 is assigned to each reinforcement assembly 30 of first housing part 11. Thereby the reinforcement assemblies are facing one another in height direction H and can optionally, at least partly, be in contact with each other.

In the embodiment the reinforcement assemblies 30 of a common pair that are arranged opposite one another in height direction H are mechanically connected with one another by means of a coupling device 35. The connection by means of the coupling device 35 can be a releasable connection, for example a screw connection. Alternatively to this, it can also be a non-releasable mechanical connection, for example a rivet connection.

For establishing the connection, coupling device 35 comprises at least one coupling element 36 and according to the example two coupling elements 36. Alternatively to the illustrated embodiment, also more than two coupling elements 36 can be used. The coupling element 36 can be a coupling bolt or a coupling bracket, for example. In the embodiment the coupling element 36 comprises a screw 37, the head of which abuts on a reinforcement assembly 30 and the nut (not illustrated) of which abuts on the reinforcement assembly 30 connected therewith and arranged opposite thereto. Preferably the head and the nut of this screw connection are not supported directly on the respective reinforcement projection 31, but abut directly or indirectly on the reinforcement element 32.

As apparent from FIGS. 1 and 2, the reinforcement projections 31 of two reinforcement assemblies 30 connected with one another are arranged between the two metallic reinforcement elements 32. In height direction H the reinforcement elements 32 are therefore arranged on sides of the reinforcement projections 31 or reinforcement assemblies 30 that are coupled with each other by means of the coupling device 35 and that are facing away from each other.

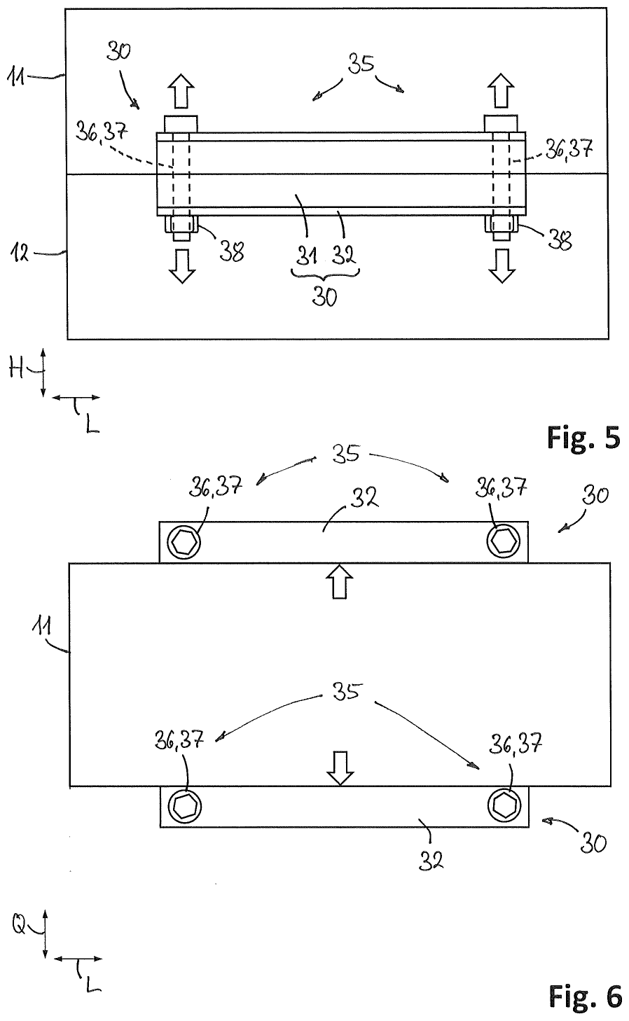

The coupling device 35 or the at least one coupling element 36 can support traction forces in height direction H, so that in case of an explosion in the interior of the explosion-proof housing 10, the forces acting in height direction H urging the two housing parts 11, 12 away from one another do not have to be supported entirely by the substance bond connection and/or the adhesive connection between the housing parts 11, 12, but are at least partly supported by the coupling device 35 (FIG. 5).

It is schematically illustrated in FIG. 6 that forces also act on the longitudinal sidewall sections 13a, 23a of the two housing parts 11, 12, due to the explosion pressure in the interior of the explosion-proof housing 10 that urge the longitudinal sidewall sections 13a, 23a away from one another outwardly and can result in a deformation. Due to the reinforcement by means of the reinforcement assemblies 30, the longitudinal sidewall sections 13a, 23a are additionally supported, particularly in the area of the connection surfaces 17, 27. Therefore, an undesired deformation is encountered. Shearing stresses or peeling stresses on the substance bond connection or the adhesive connection between the housing parts 11, 12 are therefore at least reduced.

In order to avoid an undesired deformation of the longitudinal sidewall sections in height direction H adjacent to the reinforcement assembly 30, housing parts 11, 12 can optionally comprise a stiffening assembly 42 on each longitudinal sidewall section. The length of the area in which the stiffening assembly 42 is arranged can substantially correspond to the length of the reinforcement assembly 30 arranged next to it. The length in longitudinal direction L can be minimum 50% of this length of the longitudinal sidewall section of the respective housing part 11, 12.

According to the example, stiffening assembly 42 comprises multiple stiffening ribs 43 extending parallel to each other. The stiffening ribs 43 extend parallel to a plane spanned by a height direction H and transverse direction Q, according to the example. The stiffening ribs 43 connect the respective first flange 16 of first housing part 11 or the second flange 26 of second housing part 12 with the adjoining first wall section 13 or second wall section (compare FIG. 2).

For additional stiffening, first flange 16 and/or second flange 26 can optionally and according to the illustrated embodiment, comprise a web 44. The web 44 extends with distance to the adjacent first wall section 13 or second wall section 23 and in the embodiment adjacent to the respective longitudinal sidewall section 13a, 23a of the respective housing part 11 or 12. An interstice 45 is formed between the web 44 and the adjacent wall section 13 or 23. The stiffening ribs 43 or at least a part of the provided stiffening ribs 43 extends into the interstice 45. In the embodiment each stiffening rib 43 or at least the majority of the provided stiffening ribs 43 have a section extending inside the interstice 45 and directly adjoining the respective flange 16 or 26. In the interstice 45 the stiffening ribs 43 establish a connection between web 44 and the opposite first wall section 13 or second wall section 23 (FIG. 2).

The at least one stiffening assembly 42, the at least one web 44 and the at least one reinforcement projection 31 are a monolithic part of the respective first housing part 11 or second housing part 12 in the embodiment. The first housing part 11 or the second can be manufactured by means of a molding method, for example an injection molding method.

As apparent from FIGS. 2 to 4, each reinforcement projection 31 can comprise multiple hollow spaces or chambers. These hollow spaces or chambers can be open in height direction H upwards or downwards. For separation of the individual chambers 31a from one another, each reinforcement projection 31 can comprise separation webs 31b extending orthogonal to the longitudinal direction L in the embodiment. The reinforcement element 32 attached to the reinforcement projection 31 can abut against these separation webs 31b.

The attachment of the respective reinforcement element 32 on the reinforcement projection 31 is carried out by establishment of the connection between the two assigned reinforcement assemblies 30 by means of the coupling device 35 according to the embodiment.

In the embodiment the explosion-proof housing is configured in the ignition protection category “flameproof enclosure (Ex d)”. The substance bond connection or adhesive connection on the connection surfaces 17, 27 between the two housing parts 11, 12 is preferably fluid tight and particularly gas tight. At least one of the housing parts 11, 12 can have flameproof gaps via which a gas exchange between the interior of the explosion-proof housing 10 (formed by the first interior 14 and the second interior 24) and the environment around housing 10 is possible. Therefore, ignitable gases can enter the interior of the explosion-proof housing 10 and can initiate an explosion there. Due to the described configuration of the explosion-proof housing 10 with the housing parts 11, 12 comprising a reinforcement assembly 30, the explosion-proof housing 10 withstands the explosion pressure. Also under consideration of manufacturing tolerances, the rules of the respective standard are fulfilled and nevertheless the explosion-proof housing 10 can be manufactured with low material consumption in a simple manner.

The present disclosure refers to an explosion-proof housing 10 having a non-metallic first housing part 11 and a non-metallic second housing part 12 that are connected with one another at a connection site in a substance bond manner in order to surround an interior volume of the explosion-proof housing 10 relative to an explosive atmosphere in an explosion-proof or flameproof manner. Each housing part 11, 12 comprises at least one reinforcement assembly 30, which is arranged in the area of the connection site between the two housing parts 11, 12. A reinforcement projection 31 and a metallic reinforcement element 32 are part of each reinforcement assembly 30. When the connection between the housing parts 11, 12 is established, a reinforcement assembly 30 of first housing part 11 and a reinforcement assembly 30 of second housing part 12 are preferably arranged opposite one another. These two opposite reinforcement assemblies 30 can be optionally additionally connected with one another by at least one, preferably metallic coupling element 36.

### LIST OF REFERENCE SIGNS

10 explosion-proof housing
11 first housing part
12 second housing part
13 first wall section
13a longitudinal sidewall section of first housing part
13b transverse sidewall section of first housing part
14 first interior
15 first housing opening
16 first flange
17 first connection surface
18 connection projection
23 second wall section
23a longitudinal sidewall section of second housing part
23b transverse sidewall section of second housing part
24 second interior
25 second housing opening
26 second flange
27 second connection surface
30 reinforcement assembly
31 reinforcement projection
31a chamber
31b separation web
32 reinforcement element
35 coupling device
36 coupling element
37 screw
38 nut
42 stiffening assembly
43 stiffening rib
44 web
45 interstice
H height direction
L longitudinal direction
Q transverse direction
U circumferential direction

1. An explosion-proof housing comprising:
a non-metallic first housing part surrounding a first interior accessible via a first housing opening, wherein the first housing opening is completely surrounded in circumferential direction by a first flange that comprises a first connection surface completely surrounding the first housing opening,
a non-metallic second housing part surrounding a second interior accessible via a second housing opening, wherein the second housing opening is completely surrounded in circumferential direction by a second flange that comprises a second connection surface completely surrounding the second housing opening,
wherein the first housing part and the second housing part are connected to one another at the first connection surface and second connection surface facing one another in a substance bond manner and/or by means of adhesion,
wherein the first housing part adjacent to the first connection surface outside the first interior and the second housing part adjacent to the second connection surface outside the second interior respectively comprise at least one reinforcement projection having a metallic reinforcement element attached thereon respectively.

2. The explosion-proof housing according to claim 1, wherein the first housing part comprises one reinforcement projection respectively on two opposite sides and wherein the second housing part comprises one reinforcement projection respectively on two opposite sides.

3. The explosion-proof housing according to claim 2, wherein one reinforcement projection of the second housing part is arranged opposite to each reinforcement projection of the first housing part, which are connected by means of a coupling device.

4. The explosion-proof housing according to claim 3, wherein a releasable connection is established between the reinforcement projections arranged opposite one another by means of the coupling device.

5. The explosion-proof housing according to claim 4, wherein the coupling device comprises at least one coupling element, which connects the reinforcement projections and/or reinforcement elements arranged opposite one another.

6. The explosion-proof housing according to claim 1, wherein each metallic reinforcement element is plate-shaped or strip-shaped.

7. The explosion-proof housing according to claim 1, wherein each metallic reinforcement element is a metallic reinforcement sheet material.

8. The explosion-proof housing according to claim 1, wherein each metallic reinforcement element is releasably arranged on the respective assigned reinforcement projection.

9. The explosion-proof housing according to claim 1, wherein the first connection surface and/or the second connection surface comprises or comprise at least one connection projection, which is closed in circumferential direction in a ring-shaped manner.

10. The explosion-proof housing according to claim 1, wherein each reinforcement projection and each reinforcement element are arranged at least in a center section along the respective side of the first housing part and the second housing part.

11. The explosion-proof housing according to claim 1, wherein each reinforcement projection and each reinforcement element is arranged in circumferential direction partly or entirely along a stiffening assembly of the respective housing part.

12. The explosion-proof housing according to claim 11, wherein a length of the stiffening assembly and/or an adjacent reinforcement projection and/or the reinforcement element in circumferential direction is minimum 50% of the length of the respective side of the housing part in circumferential direction.

13. The explosion-proof housing according to claim 11, wherein each stiffening assembly comprises multiple stiffening ribs that connect the respective first flange or second flange with an adjoining wall section of the respective housing part.

14. The explosion-proof housing according to claim 13, wherein each flange comprises a web that extends under formation of an interstice with distance to the wall section of the respective housing part, wherein the stiffening ribs establish a connection between the web and the wall section inside the interstice.

15. The explosion-proof housing according to claim 4, wherein the releasable connection is a screw connection.

16. The explosion-proof housing according to claim 5, wherein the at least one coupling element is a screw.

17. The explosion-proof housing according to claim 4, wherein the coupling device comprises at least one coupling element, which connects the reinforcement projections and/or reinforcement elements arranged opposite one another.

18. The explosion-proof housing according to claim 17, wherein each metallic reinforcement element is plate-shaped or strip-shaped.

19. The explosion-proof housing according to claim 18, wherein each metallic reinforcement element is a metallic reinforcement sheet material.

20. The explosion-proof housing according to claim 19, wherein each metallic reinforcement element is releasably arranged on the respective assigned reinforcement projection.
